(19) United States
(12) Patent Application Publication
(10) Pub. No.: US 2024/0421790 A1
(43) Pub. Date: Dec. 19, 2024

(54) DEVICES INCLUDING THROUGH-SUBSTRATE VIAS (TSVs) FOR BACKSIDE INTERCONNECTION, AND RELATED FABRICATION METHODS

(71) Applicant: QUALCOMM Incorporated, San Diego, CA (US)

(72) Inventors: Je-Hsiung Lan, San Diego, CA (US); Jonghae Kim, San Diego, CA (US); Ranadeep Dutta, Del Mar, CA (US)

(21) Appl. No.: 18/336,305

(22) Filed: Jun. 16, 2023

(51) Int. Cl. H03H 3/08; H03H 9/02; H03H 9/64

(52) U.S. Cl. CPC H03H 3/08; H03H 9/02574; H03H 9/02834; H03H 9/64; H01L 21/76898; H01L 23/481

(57) ABSTRACT

A package includes a device that includes electrodes disposed on a piezoelectric layer on a first, front side of a first substrate and vertical interconnect accesses (vias) that extend through the substrate to couple the electrodes to a second, back side of the first substrate. The vias may be through-substrate vias (TSVs). Employing a first substrate (e.g., silicon) in which vias can be formed, the electrodes on the front side can be coupled to interconnects on the back side to minimize electrical path distances to and from the device for a higher a Q factor. Also, a capacitor may be formed on a second, back side of the substrate and coupled to an electrode of the device by a via rather than having an electrical path from a first substrate, to an external capacitor on a package substrate. A thermal conductive path is also reduced for improved heat dissipation.

### BACKGROUND

### I. Field of the Disclosure

The technology of the disclosure relates generally to acoustic wave devices and more specifically to improving performance and reducing the size of such devices.

### II. Background

In the world of wireless communications, for example, there are many users sharing a limited number of frequencies. Such sharing may be unsuccessful if the frequencies of different users overlap each other. Therefore, wireless devices include filters to limit the frequencies of signals transmitted and received by way of a wireless interface. Acoustic wave filters have been developed to perform such filtering in a very small device package. One type of acoustic filter is a surface acoustic wave (SAW) filter which includes interdigitated electrodes on a surface of a piezoelectric material, such as lithium niobate (LN) or lithium tantalate (LT). The acoustic filter is tuned using one or more capacitors. The acoustic filter and the capacitor(s) may be mounted on a package substrate and electrically connected to each other through the package substrate. The acoustic filter may coupled to the package substrate by interconnects that are on the same surface as the electrodes and coupled to the interconnects by wires or wire traces. The electrical path between the electrodes and the capacitor extend through the wires on the piezoelectric material, the interconnects (such as solder balls), wires on the package substrate, and interconnects from the package substrate to the capacitor. Even if all of the elements of the conductive path are designed to keep resistance down, the length of the electrical path can cause losses of energy in the connection, and thus a reduction in the quality (Q) of device performance.

### SUMMARY

Aspects disclosed in the detailed description include devices including through-substrate vias (TSVs) for backside interconnection. Related methods of fabricating a device including TSVs for backside interconnection are also disclosed. An exemplary package includes a device, such as an acoustic filter, that includes electrodes disposed on a piezoelectric layer on a first, front side of a first substrate and vertical interconnect accesses (vias) that extend through the substrate to couple the electrodes to a second, back side of the first substrate. In this regard, as an example, the vias are through-substrate vias (TSVs). Employing a first substrate (e.g., a silicon layer) in which vias can be formed, the electrodes on the front side can be coupled to interconnects on the back side to minimize electrical path distances to and from the device for a higher a Q factor. As an example, rather than an electrical path passing from a first substrate of a device and through a package substrate to an external capacitor, a capacitor, such as a metal-insulator-metal (MIM) capacitor, may be formed on a second, back side of the substrate and coupled to an electrode of the device by a via. In this regard, a thermal conductive path is also reduced for improved heat dissipation. In addition, replacing a bulk component mounted on a package substrate with a MIM capacitor on the acoustic filter can also significantly reduce a total height and area of the package. In some examples, the package includes a second device that is coupled to the first device and includes through-polymer vias (TPVs) coupled to the TSVs to couple the second device to the package substrate through the first substrate.

In this regard, in one exemplary aspect, a device is disclosed. The device comprises a first substrate; a first piezoelectric layer disposed on a first side of the first substrate; and a plurality of first electrodes disposed on the first piezoelectric layer. The device further comprises a first vertical interconnect access (via) extending from a second side of the first substrate through the first substrate and the first piezoelectric layer and coupled to a first one of the plurality of first electrodes.

In another exemplary aspect, a package is disclosed. The package comprises a first device, comprising a first substrate; a first piezoelectric layer disposed on a first side of the first substrate; and a plurality of first electrodes disposed on the first piezoelectric layer. The first device further comprises a first vertical interconnect access (via) extending through the first substrate and the first piezoelectric layer to couple a first one of the plurality of first electrodes to the second side of the first substrate. The package further comprises a package substrate; and an interconnect between the second side of the first substrate and the package substrate, electrically coupling the first via to the package substrate.

In another exemplary aspect, a method of fabricating a device is disclosed, the method comprising: forming a first substrate; forming a first piezoelectric layer on a first side of the first substrate; forming a plurality of first electrodes on the first piezoelectric layer; and forming a first vertical interconnect access (via) extending through the first substrate and the first piezoelectric layer to couple a first one of the plurality of first electrodes to the second side of the first substrate.

### BRIEF DESCRIPTION OF THE DRAWINGS

FIG. 1 is a cross-sectional side view of a conventional acoustic filter package comprising a first acoustic filter and a second acoustic filter coupled to bulk components mounted on a package substrate;

FIG. 2 is a cross-sectional side view illustrating an acoustic filter package including an acoustic filter that includes electrodes disposed on a piezoelectric layer on a first side of a first substrate and vertical interconnect accesses (vias) extending through the substrate to couple the electrodes to a second side of the substrate;

FIG. 3 is flowchart illustrating a method of fabricating an acoustic filter that includes electrodes disposed on a piezoelectric layer on a first side of a first substrate and vias extending through the substrate to couple the electrodes to a second side of the substrate;

FIGS. 4A-4F are exemplary fabrication stages during fabrication of an acoustic filter that includes electrodes disposed on a piezoelectric layer on a first side of a first substrate and vias extending through the substrate to couple the electrodes to a second side of the substrate, including but not limited to the acoustic filter in FIG. 2 and according to the exemplary fabrication process in FIGS. 5A-5F;

FIG. 5A-5F is a flowchart illustrating another exemplary fabrication process of fabricating an acoustic filter including vias through a piezoelectric layer and a substrate as shown in FIG. 2, as illustrated in FIGS. 4A-4F;

FIG. 6 is a block diagram of an exemplary wireless communication device that includes an acoustic filter that includes electrodes disposed on a piezoelectric layer on a first side of a first substrate and vias extending through the substrate to couple the electrodes to a second side of the substrate in FIGS. 2 and 4F and according to, but not limited to, any of the exemplary fabrication processes of fabricating such acoustic filter in FIGS. 3 and 5A-5F; and

FIG. 7 is a block diagram of an exemplary processor-based system that can includes an acoustic filter that includes electrodes disposed on a piezoelectric layer on a first side of a first substrate and vias extending through the substrate to couple the electrodes to a second side of the substrate in FIGS. 2 and 4F and according to, but not limited to, any of the exemplary fabrication processes of fabricating such acoustic filter in FIGS. 3 and 5A-5F.

### DETAILED DESCRIPTION

Several exemplary aspects of the present disclosure are described in reference to the drawing figures. The word “exemplary” is used herein to mean “serving as an example, instance, or illustration.” Any aspect described herein as “exemplary” is not necessarily to be construed as preferred or advantageous over other aspects.

Aspects disclosed in the detailed description include devices including through-substrate vias (TSVs) for backside interconnection. Related methods of fabricating a device including TSVs for backside interconnection are also disclosed. An exemplary package includes a device, such as an acoustic filter, that includes electrodes disposed on a piezoelectric layer on a first, front side of a first substrate and vertical interconnect accesses (vias) that extend through the substrate to couple the electrodes to a second, back side of the first substrate. In this regard, as an example, the vias are through-substrate vias (TSVs). Employing a first substrate (e.g., a silicon layer) in which vias can be formed, the electrodes on the front side can be coupled to interconnects on the back side to minimize electrical path distances to and from the device for a higher a Q factor. As an example, rather than an electrical path passing from a first substrate of a device and through a package substrate to an external capacitor, a capacitor, such as a metal-insulator-metal (MIM) capacitor, may be formed on a second, back side of the substrate and coupled to an electrode of the device by a via. In this regard, a thermal conductive path is also reduced for improved heat dissipation. In addition, replacing a bulk component mounted on a package substrate with a MIM capacitor on the acoustic filter can also significantly reduce a total height and area of the package. In some examples, the package includes a second device that is coupled to the first device and includes through-polymer vias (TPVs) coupled to the TSVs to couple the second device to the package substrate through the first substrate.

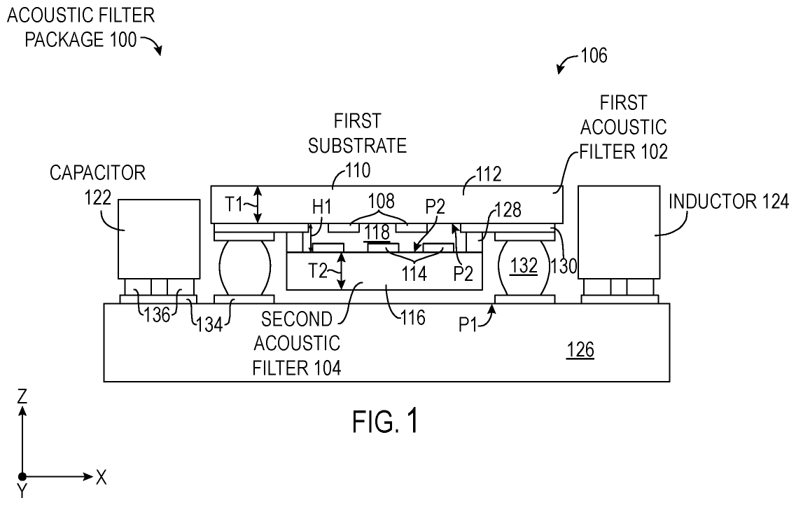

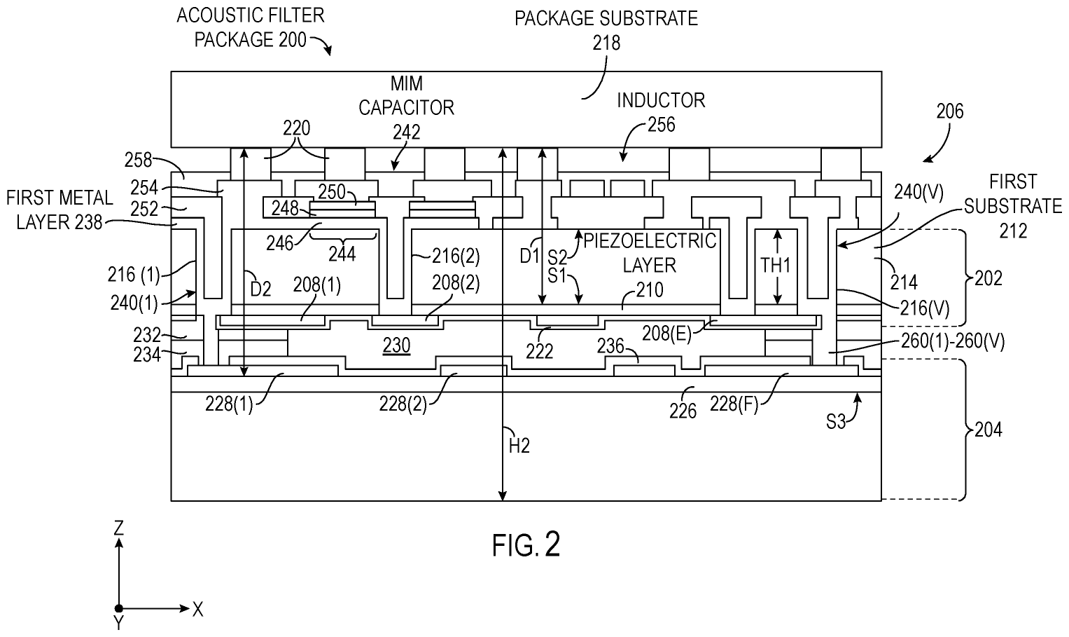

To facilitate a better understanding of exemplary aspects of a package 200 that employs a device that includes electrodes disposed on a piezoelectric layer on a first side of a first substrate and vias extending through the substrate to couple the electrodes to a second side of the substrate, starting at FIG. 2, a conventional device comprising an acoustic filter package 100 is first described with reference to FIG. 1. FIG. 1 is a cross-sectional side view of the acoustic filter package 100 comprising a first acoustic filter 102 and a second acoustic filter 104 in a duplexer circuit 106 that also includes bulk components mounted on a package substrate. The duplexer circuit 106 may be employed in a transceiver device (not shown). The first acoustic filter 102 and second acoustic filter 104 are surface acoustic wave (SAW) filters that can filter (e.g., block) undesired frequencies of an input signal to generate a filtered output signal. The first acoustic filter 102 includes electrodes 108 disposed on a first side P1 of a first substrate 110. The first substrate 110 is a piezoelectric material 112, which may be any of lanthanum tantalite (LT), lanthanum niobate (LN), or another suitable material. The second acoustic filter 104 includes electrodes 114 on a side P2 of a second substrate 116, which may also be formed of the piezoelectric material 112 or another piezoelectric material. Operation of SAW filters is well known so only a general description of the first acoustic filter 102, as an example, is provided herein and the second acoustic filter 104 is not separately described.

The electrodes 108 of the first acoustic filter 102 include interdigitated pairs of input electrodes 1081 (not shown) and output electrodes 1080 (not shown) disposed on the first substrate 110. An input signal providing an oscillating voltage to the input electrodes 1081 causes the piezoelectric material 112 of the first substrate 110 to expand and contract. The expansion and contraction creates acoustic waves that propagate across the surface P1 of the first substrate 110 and induce an oscillating voltage signal between pairs of the output electrodes 1080 that provide an output signal.

The acoustic waves on the side P1 of the first substrate 110 and the side P2 of the second substrate 116 would be attenuated or interfered with if any solid substance or material came into contact with the sides P1 and P2, which would change their performance. An air cavity 118 provides protection of both the electrodes 108 on the first substrate 110 and the electrodes 114 on the second substrate 116 if the side P1 and the side P2 are coupled in a “face-to-face” orientation to each other, to share the air cavity 118.

The duplexer circuit 106 may be “tuned” by coupling the first and second acoustic filters 102, 104 to external analog components including a capacitor 122 and an inductor 124. To couple the first and second acoustic filters 102, 104 to capacitor 122 and to the inductor 124, and also to external circuits (not shown), the first and second acoustic filters 102, 104, the capacitor 122, and the inductor 124 are coupled to (e.g., mounted on and electrically connected) a package substrate 126. Thus, the package substrate 126 must be large enough in area to include the first acoustic filter 102, the capacitor 122, and the inductor 124.

The electrodes 114 on the second side P2 of the second substrate 116 are coupled to the package substrate 126 by first interconnects 128, substrate traces 130, second interconnects 132, package traces 134, and third interconnects 136. The first interconnects 128 extend between the side P1 of the first substrate 110 and the side P2 of the second substrate 116. The substrate traces 130 extend on the side P1 of the first substrate 110 to couple the first interconnects 128 to the second interconnects 132. The second interconnects 132 extend from the side P1 of the first substrate 110 to the package substrate 126. The package traces 134 extend along the package substrate 126 and couple the second interconnects 132 to the third interconnects 136. The third interconnects 136 provide connections from the package substrate 126 to the capacitor 122 and the inductor 124. Although each of the first interconnects 128, substrate traces 130, second interconnects 132, package traces 134, and third interconnects 136 may be provided with highly conductive metal(s) (e.g., copper) having sufficiently large cross-sections to keep resistance as low as possible, there is still sufficient resistance due to the electrical path length from the electrodes 114 to the capacitor 122, for example, that the quality factor Q (pertaining to lost energy) of the acoustic filter package 100 suffers.

In another aspect, some heat generated in the second acoustic filter 104 may dissipated convectively, but the remaining heat may only be dissipated conductively. Some heat may be conducted into the first substrate 110, which can also dissipate heat convectively but the first acoustic filter 102 generates its own heat that must be dissipated. Heat from the first and second acoustic filters 102 and 104 may also be conducted to the package substrate 126 through the second interconnects 132. Thus, thermal characteristics of the acoustic filter package 100 can be a problem affecting performance and product lifetime.

In yet another aspect, the capacitor 122 and the inductor 124 may be large bulk components, having a large vertical height in a direction (e.g., Z-axis direction) orthogonal to the package substrate 126. In addition, the first substrate 110 and the second substrate 116 may each have thicknesses in a range of 300 micrometers (μm) to 500 μm. A total height of the acoustic filter package 100 is determined by a combination of the thickness T1 of the first substrate 110 and the thickness T2 of the second substrate 116, as well as the height H1 of the air cavity 118.

FIG. 2 is a cross-sectional side view of an exemplary package 200 including a first device 202 and a second device 204. The package 200 in some examples may be an acoustic filter package and, therefore may be referred to as acoustic filter package 200. In the acoustic filter package 200, the first device 202 and the second device 204 may be acoustic devices, such as acoustic filters, and may be referred to as the first acoustic filter 202 and the second acoustic filter 204. The package 200 may comprise a duplexer circuit 206 in which the first acoustic filter 202 is a receive (RX) filter and the second acoustic filter 204 is a transmit (TX) filter. Exemplary aspects of the acoustic filter package 200 are more readily understood in view of the structural features described below with reference to FIG. 2.

The first acoustic filter 202 in FIG. 2 may be a surface acoustic wave (SAW) filter that includes a plurality of first electrodes 208(1)-108(E) disposed on a piezoelectric layer 210 on a first side S1 of a first substrate 212. The piezoelectric layer 210 may be referred to as a piezoelectric film having a thickness in the range of 0.5 micrometers μm to 1.5 μm. The piezoelectric layer 210 comprises a piezoelectric material 214, which may be any of lanthanum tantalite (LT), lanthanum niobate (LN), or another suitable material.

In an exemplary aspect, the first acoustic filter 202 includes vertical interconnect accesses (vias) 216(1)-216(V) that extend through the first substrate 212 from a second side S2 to couple to the electrodes 208(1)-208(E) on the first side S1. The vias 216(1)-216(V) may also be or partially include through-substrate vias (TSVs) or, more specifically through-silicon vias (TSVs) in examples in which the first substrate 212 is formed of a material, such as silicon (Si), in which processes have been developed for forming vias. For example, the first substrate 212 may be a silicon layer having a thickness in a range of 50 μm to 200 μm. Disposing the piezoelectric layer 210 on a substrate of such material makes it possible to provide connections to the electrodes 208(1)-208(E) from the second side S2. Thus, rather than coupling a package substrate 218 to the first side S1 including the first electrodes 208(1)-208(E), the package substrate 218 can be coupled to the back side S2 of first substrate 212. Therefore, the second acoustic filter 204 is not disposed between the first substrate 212 and the package substrate 218.

In another aspect, in examples of the first substrate 212 being formed of silicon, which may be thinned according to known processes, a thickness TH1 of the first substrate 212 can be significantly reduced. For example, the first substrate 212 may be in a range from fifty (50) μm to one hundred (100) μm. Thus, electrical conduction and thermal conduction from the first electrodes 208(1)-208(E) on the first side S1 through interconnects 220 to the package substrate 218 extends over a distance D1. Keeping the distance D1 to a minimum improves the Q factor of the first acoustic filter 202 and also improves heat dissipation by conduction to the package substrate 218. To further mitigate heating on the side S1, a temperature compensation layer 222 may be disposed on the first piezoelectric layer 210 and on the plurality of first electrodes 208(1)-208(E)€.

The second acoustic filter 204 (also a SAW filter) includes a second substrate 224 with a second piezoelectric layer 226 disposed on a side S3 of the second substrate 224. The second acoustic filter 204 also includes a plurality of second electrodes 228(1)-228(F) disposed on the second piezoelectric layer 226. The second substrate 224 may be silicon, like the first substrate 212, or another material.

The second acoustic filter 204 in this example is coupled face-to-face to the first acoustic filter 202 to form an air cavity 230 therebetween for protection of the acoustic activity of both of the first acoustic filter 202 and the second acoustic filter 204. In this regard, the acoustic filter package 200 includes polymer layer 232 on the first acoustic filter 202 and polymer layer 234 on the second acoustic filter 204. The polymer layers 232, 234 are disposed between the first and second substrates 212, 224 and around the plurality of first electrodes 208(1)-208(E) and the plurality of second electrodes 228(1)-228(F) to provide the air cavity 230. A temperature compensation layer 236 is formed over the second piezoelectric layer 226 and the plurality of second electrodes 228(1)-228(F).

The plurality of vias 216(1)-216(V) couple the plurality of first electrodes 208(1)-208(E) to a first metal layer 238 on the second side S2 of the first substrate 212. The first metal layer 238 can further couple the plurality of first electrodes 208(1)-208(E) to the interconnects 220, which couple the first acoustic filter 202 to the package substrate 218. In addition to the features shown in FIG. 2, there may be other features that are not shown due to the first substrate 212 being formed of a semiconductive material such as silicon. For example, a protective layer (not shown) may be disposed between the first metal layer 238 and the first substrate 212 and also between the piezoelectric layer 210 and the first substrate 212.

The plurality of vias 216(1)-216(V) are formed in voids 240(1)-240(V) when the first metal layer 238 is formed on the second side S2. In addition to providing the plurality of vias 216(1)-216(V) and coupling the plurality of vias 216(1)-216(V) to the interconnects 220, a capacitor 242, which is a MIM capacitor 242 in this example, may also be formed on the first metal layer 238. A first portion 244 of the first metal layer 238 may provide a first electrode 246 of the MIM capacitor 242. The MIM capacitor 242 also includes a first dielectric layer 248 disposed on the first portion 244 of the first metal layer 236 and a second electrode 250 of the MIM capacitor 242 is formed on the first dielectric layer 248.

As shown in FIG. 2, the first metal layer 238 is patterned to form the first electrode 246 of the MIM capacitor 242, to provide traces from the vias 216(1)-216(V) to both the MIM capacitor 242 and the interconnects 220. A second dielectric layer 252, which may be a dry film fill (e.g., polymer material), insulates respective portions of the first metal layer 238 from each other and also from a second metal layer 254. The second dielectric layer 252 is also patterned to allow for vertical connections to be formed between the first metal layer 238 and the second metal layer 254. The second metal layer 254 is patterned to provide landing locations for interconnects 220 (e.g., solder bumps or pillars) which may be formed on the second metal layer 254 to provide electrical connections between the acoustic filter package 200 and an external circuit (not shown) through the package substrate 218. The second metal layer 254 may also be patterned to form an inductor 256 on the second dielectric layer 252. For example, the inductor 256 may be formed by spiral traces of the second metal layer 254. A third dielectric 258, such as an inter-layer dielectric (ILD), may also be deposited or formed on the second metal layer 254 (e.g., between the interconnects 220, to protect and insulate the second metal layer 254 from external contact.

In another exemplary aspect, the acoustic filter package 200 includes through-polymer vias (TPVs) 260(1)-260(P) extending through the polymer layers 232 and 234 to couple the plurality of second electrodes 228(1)-228(F) to the vias 216(1)-216(V). In this regard, the second acoustic filter 204 is electrically and thermally coupled to the package substrate 218 from a distance D2 including the TPVs 260(1)-260(P) and the thickness TH1 of the first substrate 212. The short distances D1 and D2 allow the electrical paths of the duplexer circuit 206 to have lower resistance, for a high Q value, and also have improved thermal dissipation.

Other beneficial aspects of the acoustic filter package 200 include a lower height in the vertical direction (e.g., Z-axis direction) orthogonal to the package substrate 218 and, with the MIM capacitor 242 and the inductor 256 provided on the first acoustic filter 202 rather than adjacent to the first acoustic filter 202 on the package substrate 218, the package substrate may be smaller in area.

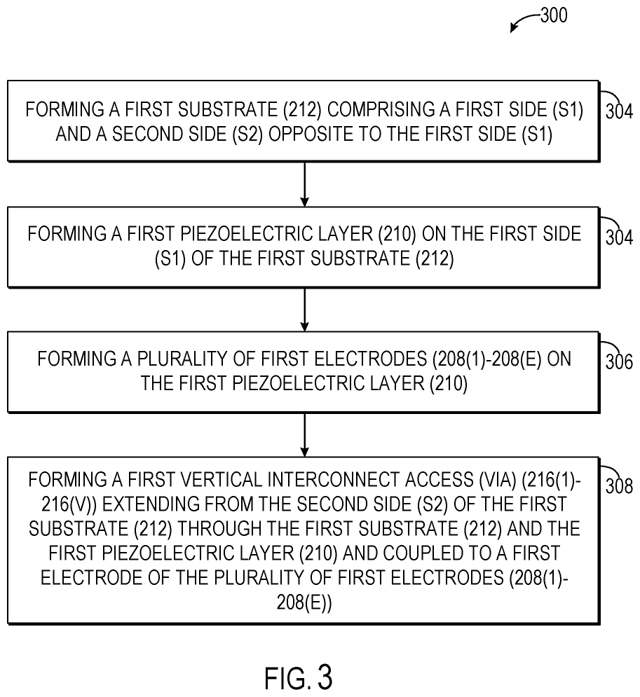

FIG. 3 is flowchart illustrating a method 300 of fabricating a device, such as an acoustic filter that includes electrodes disposed on a piezoelectric layer on a first side of a first substrate and vertical interconnect accesses (vias) extending through the substrate to couple the electrodes to a second side of the substrate, such as the acoustic filter 202 in FIG. 2. The method 300 includes forming a first substrate 212 comprising a first side S1 and a second side S2 opposite to the first side S1 (block 302), and forming a first piezoelectric layer 210 on the first side S1 of the first substrate 212 (block 304). The method 300 further includes forming a plurality of first electrodes 208(1)-208(E) on the first piezoelectric layer 210 (block 306); and forming a first via 216(1)-216(V) extending from the second side S2 of the first substrate 212 through the first substrate 212 and the first piezoelectric layer 210 and coupled to a first one of the plurality of first electrodes 208(1)-208(E) (block 308).

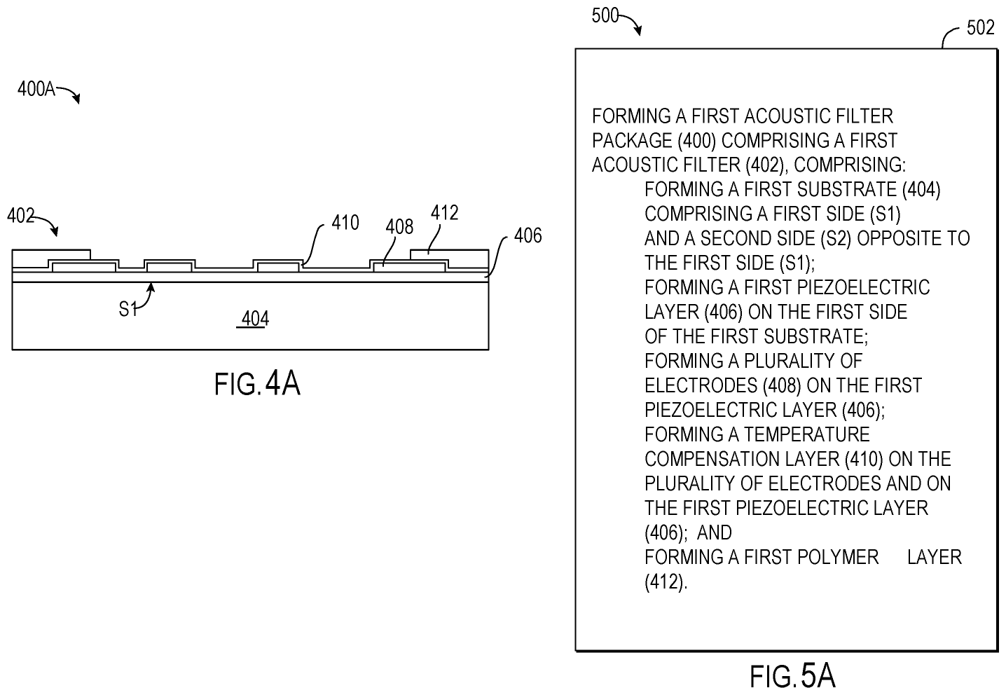

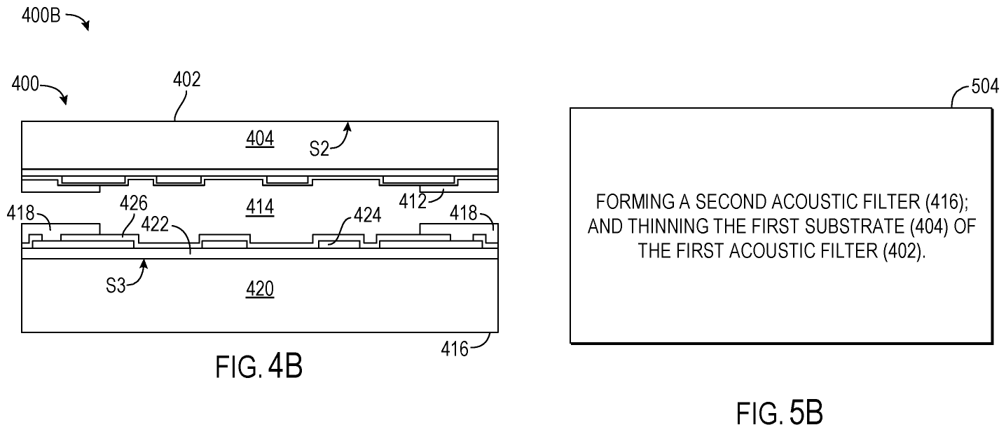

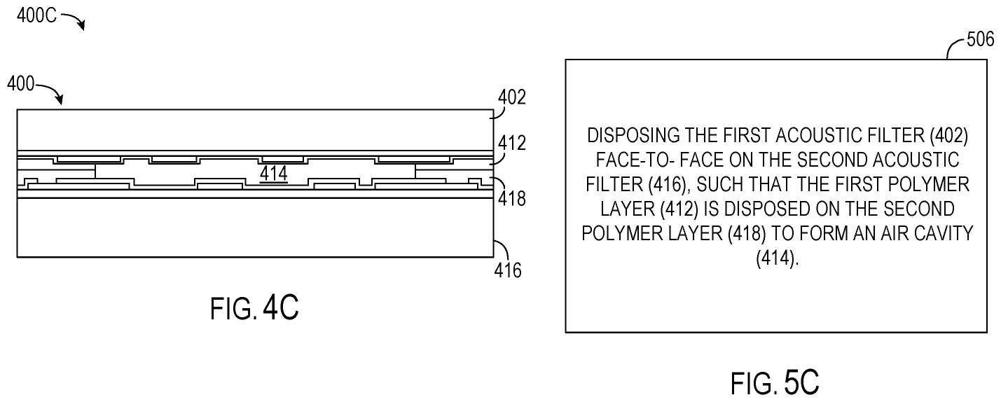

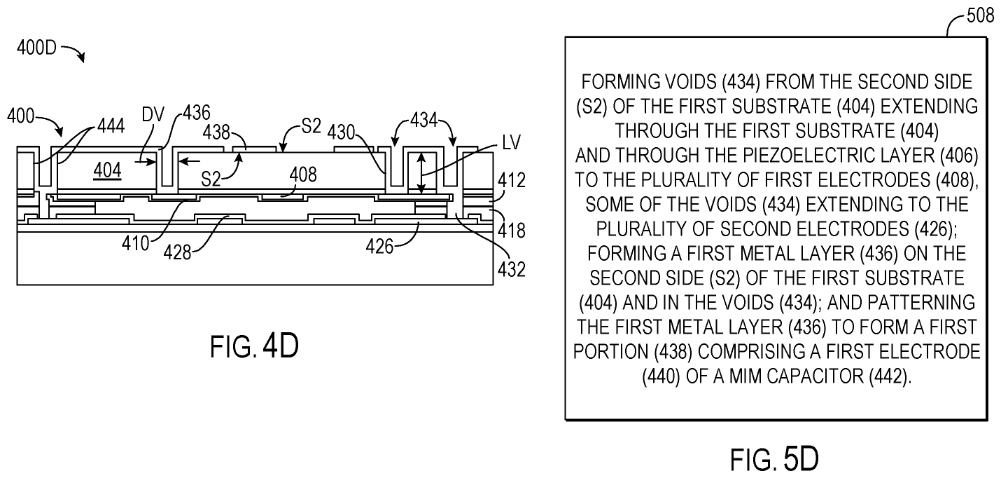

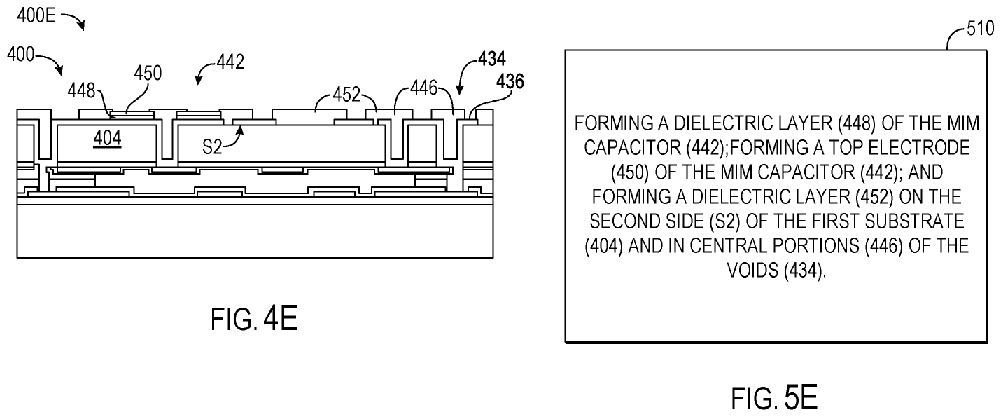

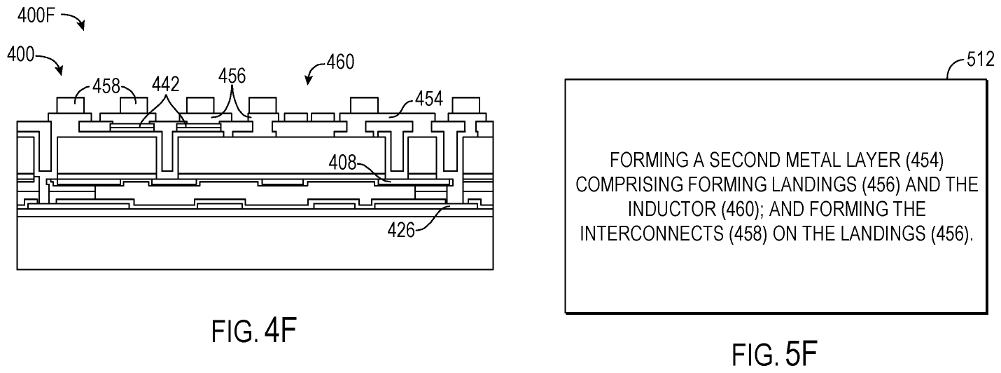

FIGS. 4A-4F are illustrations of exemplary fabrication stages of an acoustic filter package that includes a first acoustic filter with electrodes disposed on a piezoelectric layer on a first side of a first substrate and vias extending through the substrate to couple the electrodes to a second side of the substrate, including but not limited to the acoustic filter 202 in FIG. 2 and according to the exemplary fabrication process in the flowchart in FIGS. 5A-5F.

FIG. 4A is an illustration of a cross-sectional side view of a first device 402, also referred to as acoustic filter 402, in a first fabrication stage 400A of an acoustic filter package 400. FIG. 4A shows a first substrate 404, which may be formed of a material, such as silicon or an insulator, for which there are processes for forming conductive vias. A piezoelectric layer 406 (piezoelectric film) is disposed on a first side S1 of the first substrate 404 and first electrodes 408 are disposed on the first piezoelectric layer 406. In some examples, such as when the first substrate 404 is formed of a semiconductor material such as silicon, there may be a dielectric or insulating layer between the first piezoelectric layer 406 and the first substrate 404. A temperature compensation layer 410 is formed over the first electrodes 408 and on the piezoelectric layer 406 between the first electrodes 408. Polymer layer 412 is disposed on the temperature compensation layer 410 around an area A₄₁₄ of the first piezoelectric layer 406 corresponding to an air cavity 414 in which acoustic waves or activity occurs during operation of the first acoustic filter 402.

FIG. 5A is an illustration of a block 502 in a process 500 for fabricating the acoustic filter package 400 including the acoustic filter 402 in the first fabrication stage 400A shown in FIG. 4A. The block 502 includes forming a first substrate 404 and forming a first piezoelectric layer 406 on a first side S1 of the first substrate 404. The process 500 further includes forming a plurality of first electrodes 408 on the first piezoelectric layer 406. The block 502 includes forming a first temperature compensation layer 410 on the electrodes 408 and the first piezoelectric layer 406, and forming a first polymer layer 412, which may be employed to couple the first substate 404 to another substrate and form the air cavity 414 (see FIG. 4B).

FIG. 4B is a cross-sectional side view of the acoustic filter package 400 in a second fabrication stage 400B of the acoustic filter package 400. FIG. 4B shows the first acoustic filter 402 from FIG. 4A after the second side S2 of the first substrate 404 is thinned by backside grinding or another process to reduce thickness of the first substrate 404. FIG. 4B also shows a second acoustic filter 416 fabricated according to the process in FIG. 5A. The second acoustic filter 416 includes second polymer layer 418 for forming the air cavity 414. In FIG. 4B, the first acoustic filter 402 is inverted (e.g., turned upside down) to be face-to-face with the second acoustic filter 416 and the first and second polymer layers 412 and 418 opposite to each other.

FIG. 5B is an illustration of a block 504 in the process 500 for fabricating the acoustic filter package 400 in the second fabrication stage 400B shown in FIG. 4B. The block 504 includes forming a second acoustic filter 416 comprising a second substrate 420, a second piezoelectric layer 422 on the third side S3 of the second substrate 420, and a plurality of second electrodes 424 disposed on the second piezoelectric layer 422. The process 504 further includes forming a temperature compensation layer 426. The process 504 includes forming the second polymer layer 418 on the second piezoelectric layer 422. The process 504 further includes thinning (e.g., the back side of) the second side S2 of the first substrate 404.

FIG. 4C is a cross-sectional side view of the acoustic filter package 400 in a third fabrication stage 400C of the acoustic filter package 400. FIG. 4C shows the first acoustic filter 402 from FIG. 4B inverted to be face-to-face with the second acoustic filter 416 and disposed on the second acoustic filter 416, such that the first polymer layer 412 is in contact with the second polymer layer 418 to form an air cavity 414 between the first piezoelectric layer 406 and the second piezoelectric layer 422.

FIG. 5C is an illustration of a block 506 in the process 500 for fabricating the acoustic filter package 400 in the third fabrication stage 400C shown in FIG. 4C. The block 506 includes disposing the first acoustic filter 402 face-to-face on the second acoustic filter 416, such that the first polymer layer 412 is disposed on the second polymer layer 418 to form the air cavity 414.

FIG. 4D is a cross-sectional side view of the acoustic filter package 400 in a fourth fabrication stage 400D of the acoustic filter package 400. FIG. 4D shows the acoustic filter package 400 from FIG. 4C with partially formed vias 430, also referred to as through-substrate vias (TSVs) 430 (which may be through-silicon vias) extending from a second side S2 of the first substrate 404 to couple to the plurality of first electrodes 408. FIG. 4D also shows through-polymer vias (TPVs) 432 extending through the first and second polymer layers 412 and 418, respectively, and coupled to some of the first plurality of TSVs 430. The TPVs 432 couple the plurality of second electrodes 426 to the TSVs 430, which are further coupled to the plurality of first electrodes 408.

FIG. 4D shows that the partially formed vias 430 are voids 434 through the first substrate 404 in which a first metal layer 436 has been deposited. The first metal layer 436 is also patterned on the second side S2 of the first substrate 404 to include a portion 438 forming a first electrode 440 of a MIM capacitor 442 (see FIG. 4E). The TPVs 432 having a smaller diameter than the TSVs 430 may be fully formed of the first metal layer 436 deposited in the voids 434. The TSVs 430 have a lower aspect ratio, so the first metal layer 436 is merely deposited on sides 444 of the voids 434, leaving a central portion 446 of the TSVs 430 hollow at stage 400D. Where the voids 434 are formed as cylindrical holes through the first substrate 404, the first metal layer 436 deposited on the sides 444 of the voids 434 form cylindrical conductors. Generally, TSVs for signals in integrated circuits are typically much higher aspect ratio, which is defined as a ratio of a length of the via to a diameter of the via (e.g., nine (9) to one (1)) than the vias 430 to minimize occupied area. In contrast, the acoustic filter 402 employs a small number of signals, so area is not limited in the first substrate 404. Therefore, TSVs 430 can be provided with a low aspect ratio (e.g., less than about three (3) to one (1) (3/1), and more specifically in a range from 0.5 to 2.0) for a high Q connection between the plurality of first electrodes 408 to the first metal layer 436. A length LV of the TSVs 430 extend from one of the electrodes 408 to the second side S2 of the first substrate 404, and in particular to the first metal layer 436. A diameter DV of the TSVs 430 is from a side 444 to an opposite side 444.

FIG. 5D is an illustration of a block 508 in the process 500 for fabricating the acoustic filter package 400 in the fourth fabrication stage 400D shown in FIG. 4D. The block 508 includes forming voids 434 (e.g., by etching) from the second side S2 of the first substrate 404 extending through the first substrate 404 and through the piezoelectric layer 406 to the plurality of first electrodes 408. Forming the voids 434 includes extending some of the voids 434 through the temperature compensation layers 410 and 428, and through the first polymer layer 412 and the second polymer layer 418 to the plurality of second electrodes 426. The process 508 further includes forming a first metal layer 436 on the second side S2 of the first substrate 404 and in the voids 434. Forming the first metal layer 436 may include depositing, in some manner, a layer of a metal such as copper on the second side S2 of the first substrate 404 and also on the sides 444 of the voids 434. Forming the first metal layer also includes patterning (e.g., using photolithographic methods) the first metal layer 436, to form the first portion 438 of the first metal layer 436 comprising a first electrode 440 of the MIM capacitor 442.

FIG. 4E is a cross-sectional side view of the acoustic filter package 400 in a fifth fabrication stage 400E of the acoustic filter package 400. FIG. 4D shows the acoustic filter package 400 from FIG. 4D further including a dielectric layer 448 of the MIM capacitor 442 and a top electrode 450 of the MIM capacitor 442 on the portion 438 of the first metal layer 436 employed as the first electrode 440. FIG. 4E also shows a dielectric material 452, which may be a dry film fill (e.g., a polymer or an appropriate non-conductive material), deposited in the hollow central portions 446 of the voids 434. Thus, each of the plurality of first vias 408 comprises a cylindrical conductor having a polymer central portion 446. The dielectric material 452 is also formed on the second side S2 of the first substrate 404 where the first metal layer 436 has been removed and also on areas of the first metal layer 436 to provide a separation of a second metal layer (not shown) from the first metal layer 436 as needed.

FIG. 5E is an illustration of block 510 in process 500 for fabricating the acoustic filter package 400 in the fifth fabrication stage 400E shown in FIG. 4E. The block 510 includes forming the dielectric layer 448 of the MIM capacitor 442, forming the top electrode 450 of the MIM capacitor 442, forming the dielectric material 452 on the second side S2 of the first substrate 404 and in the central portions 446 of the voids 434. Forming the dielectric material 452 includes forming the dielectric layer on areas of the first substrate 404 in which the first metal layer 436 is absent, and on areas of the first metal layer 436.

FIG. 4F is a cross-sectional side view of the acoustic filter package 400 in a sixth fabrication stage 400F of the acoustic filter package 400. FIG. 4F shows the acoustic filter package 400 from FIG. 4E further including a second metal layer 454 providing landings 456 for interconnects 458, which may be used to couple to a package substrate (not shown). The second metal layer 454 is also patterned to form an inductor 460. The second metal layer 454 couples the interconnects 458 to the plurality of first electrodes 408, the plurality of second electrodes 426, the MIM capacitor 442, and the inductor 460.

FIG. 5F is an illustration of block 512 in process 500 for fabricating the acoustic filter package 400 in the sixth fabrication stage 400F shown in FIG. 4F. The block 512 includes forming a second metal layer 454 comprising forming landings 456 and the inductor 460, and forming the interconnects 458 on the landings 456.

Electronic devices that include includes an acoustic filter that includes electrodes disposed on a piezoelectric layer on a first side of a first substrate and vias extending through the substrate to couple the electrodes to a second side of the substrate in FIGS. 1 and 4F and according to, but not limited to, any of the exemplary fabrication processes of fabricating such acoustic filter in FIGS. 3 and 5A-5F, and according to any aspects disclosed herein, may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, laptop computer, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

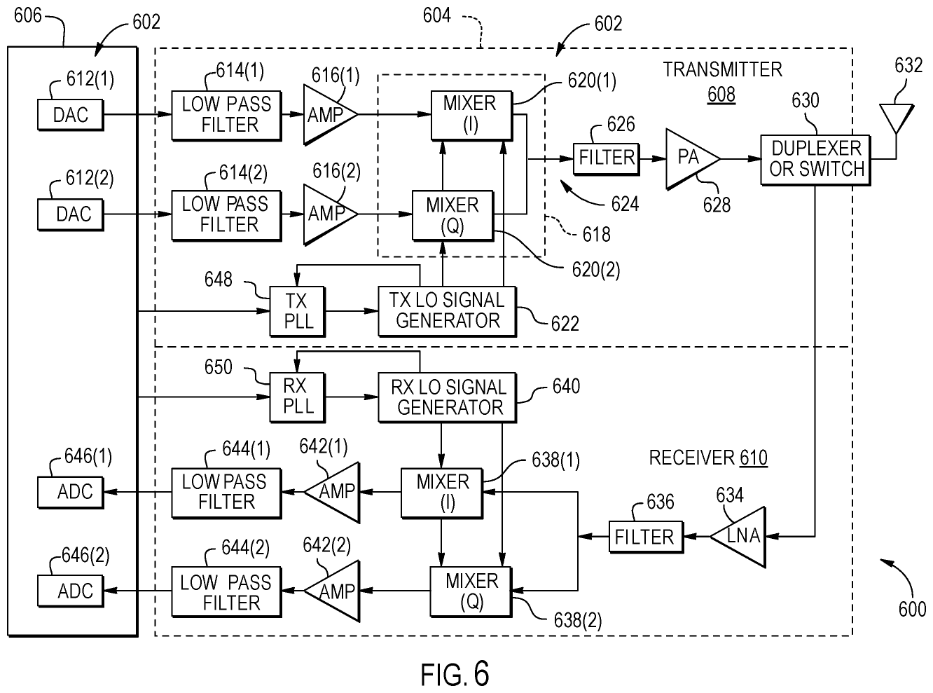

In this regard, FIG. 6 illustrates a block diagram of an exemplary wireless communications device 600 that includes radio frequency (RF) components formed from one or more ICs 602, wherein any of the ICs 602 can include an acoustic filter that includes electrodes disposed on a piezoelectric layer on a first side of a first substrate and vias extending through the substrate to couple the electrodes to a second side of the substrate as illustrated in FIGS. 1 and 4F and according to, but not limited to, any of the exemplary fabrication processes of fabricating such acoustic filter in FIGS. 3 and 5A-5F, and according to any aspects disclosed herein. The wireless communications device 600 may include or be provided as examples in any of the above-referenced devices. As shown in FIG. 6, the wireless communications device 600 includes a transceiver 604 and a data processor 606. The data processor 606 may include a memory to store data and program codes. The transceiver 604 includes a transmitter 608 and a receiver 610, which support bi-directional communications. In general, the wireless communications device 600 may include any number of transmitters 608 and/or receivers 610 for any number of communication systems and frequency bands. All or a portion of the transceiver 604 may be implemented on one or more analog ICs, RF ICs (RFICs), mixed-signal ICs, etc.

The transmitter 608 or the receiver 610 may be implemented with a super-heterodyne or direct-conversion architecture. In the super-heterodyne architecture, a signal is frequency-converted between RF and baseband in multiple stages, e.g., from RF to an intermediate frequency (IF) in one stage and then from IF to baseband in another stage. In the direct-conversion architecture, a signal is frequency-converted between RF and baseband in one stage. The super-heterodyne and direct-conversion architectures may use different circuit blocks and/or have different requirements. In the wireless communications device 600 in FIG. 6, the transmitter 608 and the receiver 610 are implemented with the direct-conversion architecture.

In the transmit path, the data processor 606 processes data to be transmitted and provides I and Q analog output signals to the transmitter 608. In the exemplary wireless communications device 600, the data processor 606 includes digital-to-analog converters (DACs) 612(1), 612(2) for converting digital signals generated by the data processor 606 into I and Q analog output signals, e.g., I and Q output currents, for further processing.

Within the transmitter 608, lowpass filters 614(1), 614(2) filter the I and Q analog output signals, respectively, to remove undesired signals caused by the prior digital-to-analog conversion. Amplifiers (AMPs) 616(1), 616(2) amplify the signals from the lowpass filters 614(1), 614(2), respectively, and provide I and Q baseband signals. An upconverter 618 upconverts the I and Q baseband signals with I and Q transmit (TX) local oscillator (LO) signals from a TX LO signal generator 622 through mixers 620(1), 620(2) to provide an upconverted signal 624. A filter 626 filters the upconverted signal 624 to remove undesired signals caused by the frequency upconversion and noise in a receive frequency band. A power amplifier (PA) 628 amplifies the upconverted signal 624 from the filter 626 to obtain the desired output power level and provides a transmit RF signal. The transmit RF signal is routed through a duplexer or switch 630 and transmitted via an antenna 632.

In the receive path, the antenna 632 receives signals transmitted by base stations and provides a received RF signal, which is routed through the duplexer or switch 630 and provided to a low noise amplifier (LNA) 634. The duplexer or switch 630 is designed to operate with a specific receive (RX)-to-TX duplexer frequency separation, such that RX signals are isolated from TX signals. The received RF signal is amplified by the LNA 634 and filtered by a filter 636 to obtain a desired RF input signal. Downconversion mixers 638(1), 638(2) mix the output of the filter 636 with I and Q RX LO signals (i.e., LO_I and LO_Q) from an RX LO signal generator 640 to generate I and Q baseband signals. The I and Q baseband signals are amplified by AMPs 642(1), 642(2) and further filtered by lowpass filters 644(1), 644(2) to obtain I and Q analog input signals, which are provided to the data processor 606. In this example, the data processor 606 includes analog-to-digital converters (ADCs) 646(1), 646(2) for converting the analog input signals into digital signals to be further processed by the data processor 606.

In the wireless communications device 600 of FIG. 6, the TX LO signal generator 622 generates the I and Q TX LO signals used for frequency upconversion, while the RX LO signal generator 640 generates the I and Q RX LO signals used for frequency downconversion. Each LO signal is a periodic signal with a particular fundamental frequency. A TX phase-locked loop (PLL) circuit 648 receives timing information from the data processor 606 and generates a control signal used to adjust the frequency and/or phase of the TX LO signals from the TX LO signal generator 622. Similarly, an RX PLL circuit 650 receives timing information from the data processor 606 and generates a control signal used to adjust the frequency and/or phase of the RX LO signals from the RX LO signal generator 640.

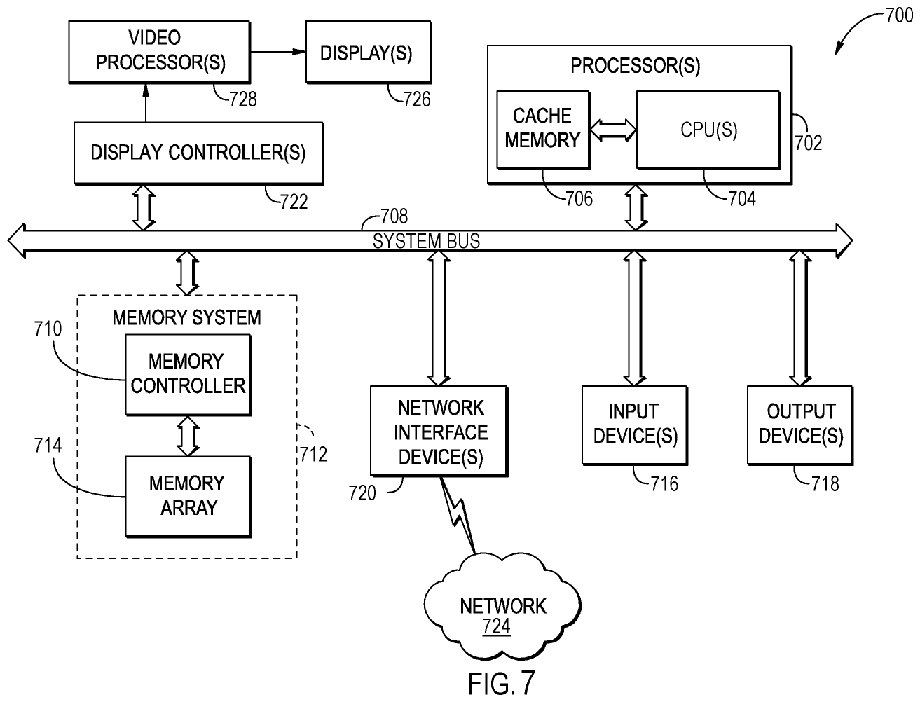

FIG. 7 illustrates a block diagram of an example of a processor-based system 700 that can employ integrated circuits, including an acoustic filter that includes electrodes disposed on a piezoelectric layer on a first side of a first substrate and vias extending through the substrate to couple the electrodes to a second side of the substrate as illustrated in FIGS. 1 and 4F and according to, but not limited to, any of the exemplary fabrication processes of fabricating such acoustic filter in FIGS. 3 and 5A-5F. In this example, the processor-based system 700 includes one or more central processor units (CPUs) 702, which may also be referred to as CPU or processor cores, each including one or more processors 704. The CPU(s) 702 may have cache memory 706 coupled to the processor(s) 704 for rapid access to temporarily stored data. The CPU(s) 702 is coupled to a system bus 708 and can intercouple master and slave devices included in the processor-based system 700. As is well known, the CPU(s) 702 communicates with these other devices by exchanging address, control, and data information over the system bus 708. For example, the CPU(s) 702 can communicate bus transaction requests to a memory controller 710 as an example of a slave device. Although not illustrated in FIG. 7, multiple system buses 708 could be provided wherein each system bus 708 constitutes a different fabric.

Other master and slave devices can be connected to the system bus 708. As illustrated in FIG. 7, these devices can include a memory system 712 that includes the memory controller 710 and one or more memory arrays 714, one or more input devices 716, one or more output devices 718, one or more network interface devices 720, and one or more display controllers 722, as examples. The input device(s) 716 can include any type of input device, including, but not limited to, input keys, switches, voice processors, etc. The output device(s) 718 can include any type of output device, including, but not limited to, audio, video, other visual indicators, etc. The network interface device(s) 720 can be any device configured to allow an exchange of data to and from a network 724. The network 724 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 720 can be configured to support any type of communications protocol desired.

The CPU(s) 702 may also be configured to access the display controller(s) 722 over the system bus 708 to control information sent to one or more displays 726. The display controller(s) 722 sends information to the display(s) 726 to be displayed via one or more video processors 728, which process the information to be displayed into a format suitable for the display(s) 726. The display(s) 726 can include any type of display, including, but not limited to, a cathode ray tube (CRT), a liquid crystal display (LCD), a plasma display, or a light-emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium wherein any such instructions are executed by a processor or other processing device, or combinations of both. As examples, the devices and components described herein may be employed in any circuit, hardware component, integrated circuit (IC), or IC chip. Memory disclosed herein may be any type and size of memory and may be configured to store any desired information. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer-readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. Alternatively, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using various technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

Implementation examples are described in the following numbered clauses:
1. A device, comprising:
   a first substrate comprising a first side and a second side opposite the first side;
   a first piezoelectric layer disposed on the first side of the first substrate;
   a plurality of first electrodes disposed on the first piezoelectric layer; and
   a first vertical interconnect access (via) extending through the first substrate and
   the first piezoelectric layer to couple a first electrode of the plurality of
   first electrodes to the second side of the first substrate.
2. The device of clause 1, further comprising a capacitor formed on the second side of the first substrate and coupled to the first via.
3. The device of clause 2, further comprising a first metal layer disposed on the second side of the first substrate and comprising a first electrode of the capacitor coupled to the first via.
4. The device of clause 3, the capacitor further comprising:
   a dielectric layer disposed on the first metal layer; and
   a second metal layer disposed on the dielectric layer.
5. The device of any of clauses 1-4, further comprising an inductor formed in a first metal layer disposed on the second side of the first substrate.
6. The device of any of clauses 1-5, further comprising a second via extending from the second side of the first substrate through the first substrate and the first piezoelectric layer and coupled to a second one of the plurality of first electrodes.
7. The device of any of clauses 1-6, wherein the first substrate comprises a silicon substrate.
8. The device of any of clauses 1-7, wherein:
   a thickness of the first substrate between the first side and the second side is in a range from fifty (50) to one hundred (100) micrometers (μm); and
   a thickness of the first piezoelectric layer is in a range from 0.5 to 1.5 μm.
9. The device of any of clauses 1-8, wherein the first via comprises a cylindrical conductor having a non-conductive central portion.
10. The device of clause 9, wherein:
   the first via comprises:
      a first length extending between the first one of the plurality of first electrodes and the second side of the first substrate; and
      a diameter of the cylindrical conductor; and
   a ratio of the first length to the diameter is less than three (3/1).
11. The device of any of clauses 2-10, wherein the capacitor comprises a metal-insulator-metal (MIM) capacitor.
12. The device of any of clauses 1-11 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.
13. A package, comprising:
   a first device, comprising:
      a first substrate comprising a first side and a second side opposite to the first side;
      a first piezoelectric layer disposed on the first side of the first substrate;
      a plurality of first electrodes disposed on the first piezoelectric layer; and
      a first vertical interconnect access (via) extending through the first substrate and the first piezoelectric layer to couple a first electrode of the plurality of first electrodes to the second side of the first substrate;
   a package substrate; and
   a first interconnect between the second side of the first substrate and the package substrate, electrically coupling the first via to the package substrate.
14. The package of clause 13, further comprising:
   a second device, comprising:
      a second substrate;
      a second piezoelectric layer disposed on a third side of the second substrate; and
      a plurality of second electrodes disposed on the second piezoelectric layer; and
   a polymer layer disposed between the first piezoelectric layer and the second piezoelectric layer and forming an air cavity between the first piezoelectric layer and the second piezoelectric layer.
15. The package of clause 14, further comprising a through-polymer via (TPV) extending through the polymer layer and coupled to the first via and a first one of the plurality of second electrodes,
   wherein the second device is electrically coupled to the package substrate through the first via and the TPV.
16. The package of any of clauses 13-15, wherein the first substrate comprises a silicon substrate.
17. The package of any of clauses 13-16, the acoustic filter further comprising a capacitor formed on the second side of the first substrate and coupled to one of the plurality of first electrodes.
18. The package of clause 17, wherein the capacitor comprises a metal-insulator-metal (MIM) capacitor.
19. The package of any of clauses 14-18, further comprising a duplexer, wherein the first acoustic filter comprises a receive filter and the second acoustic filter comprises a transmit filter.
20. A method of fabricating a device, the method comprising:
   forming a first substrate comprising a first side and a second side opposite to the first side;
   forming a first piezoelectric layer on the first side of the first substrate;
   forming a plurality of first electrodes on the first piezoelectric layer; and
   forming a first vertical interconnect access (via) extending through the first substrate and the first piezoelectric layer to couple a first one of the plurality of first electrodes to the second side of the first substrate.
21. The method of clause 20, further comprising forming a capacitor on the second side of the first substrate coupled to one of the plurality of first electrodes.
22. The method of clause 20 or 21, further comprising forming an inductor on the second side of the first substrate coupled to one of the plurality of first electrodes.
23. The method of any of clauses 20-22, wherein forming the first via comprises:
   etching a void through the first substrate and the first piezoelectric layer; and
   forming a first metal layer on the second side of the first substrate and in the void,
   wherein a portion of the first metal layer comprises a first electrode of the capacitor.
24. The method of any of clauses 21-23, further comprising forming an interconnect configured to couple the device to a package substrate;
   wherein:
   forming the capacitor further comprises:
      forming a dielectric layer on the first electrode of the capacitor; and
      forming a second metal layer on the dielectric layer, the second metal layer comprising a second electrode of the capacitor; and
   forming the interconnect comprises forming the interconnect on the second metal layer.
25. The method of any of clauses 20-24, further comprising:
   coupling a second device on a second substrate to the first side of the first substrate, wherein a polymer layer is disposed between the first side of the first substrate and the second device and the polymer layer forms an air cavity; and
   forming a through-polymer via through the polymer layer and extending between the first via and the second device.

What is claimed is:

1. A device, comprising:
a first substrate comprising a first side and a second side opposite the first side;
a first piezoelectric layer disposed on the first side of the first substrate;
a plurality of first electrodes disposed on the first piezoelectric layer; and
a first vertical interconnect access (via) extending through the first substrate and the first piezoelectric layer to couple a first electrode of the plurality of first electrodes to the second side of the first substrate.

2. The device of claim 1, further comprising a capacitor formed on the second side of the first substrate and coupled to the first via.

3. The device of claim 2, further comprising a first metal layer disposed on the second side of the first substrate and comprising a first electrode of the capacitor coupled to the first via.

4. The device of claim 3, the capacitor further comprising:
a dielectric layer disposed on the first metal layer; and
a second metal layer disposed on the dielectric layer.

5. The device of claim 1, further comprising an inductor formed in a first metal layer disposed on the second side of the first substrate.

6. The device of claim 1, further comprising a second via extending from the second side of the first substrate through the first substrate and the first piezoelectric layer and coupled to a second one of the plurality of first electrodes.

7. The device of claim 1, wherein the first substrate comprises a silicon substrate.

8. The device of claim 1, wherein:
a thickness of the first substrate between the first side and the second side is in a range from fifty (50) to one hundred (100) micrometers (μm); and
a thickness of the first piezoelectric layer is in a range from 0.5 to 1.5 μm.

9. The device of claim 1, wherein the first via comprises a cylindrical conductor having a non-conductive central portion.

10. The device of claim 9, wherein:
the first via comprises:
a first length extending between the first one of the plurality of first electrodes and the second side of the first substrate; and
a diameter of the cylindrical conductor; and
a ratio of the first length to the diameter is less than three (3/1).

11. The device of claim 2, wherein the capacitor comprises a metal-insulator-metal (MIM) capacitor.

12. The device of claim 1 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

13. A package, comprising:
a first device, comprising:
a first substrate comprising a first side and a second side opposite to the first side;
a first piezoelectric layer disposed on the first side of the first substrate;
a plurality of first electrodes disposed on the first piezoelectric layer; and
a first vertical interconnect access (via) extending through the first substrate and the first piezoelectric layer to couple a first electrode of the plurality of first electrodes to the second side of the first substrate;
a package substrate; and
a first interconnect between the second side of the first substrate and the package substrate, electrically coupling the first via to the package substrate.

14. The package of claim 13, further comprising:
a second device, comprising:
a second substrate;
a second piezoelectric layer disposed on a third side of the second substrate; and
a plurality of second electrodes disposed on the second piezoelectric layer; and
a polymer layer disposed between the first piezoelectric layer and the second piezoelectric layer and forming an air cavity between the first piezoelectric layer and the second piezoelectric layer.

15. The package of claim 14, further comprising a through-polymer via (TPV) extending through the polymer layer and coupled to the first via and a first one of the plurality of second electrodes,
wherein the second device is electrically coupled to the package substrate through the first via and the TPV.

16. The package of claim 13, wherein the first substrate comprises a silicon substrate.

17. The package of claim 13, the acoustic filter further comprising a capacitor formed on the second side of the first substrate and coupled to one of the plurality of first electrodes.

18. The package of claim 17, wherein the capacitor comprises a metal-insulator-metal (MIM) capacitor.

19. The package of claim 14, further comprising a duplexer, wherein the first acoustic filter comprises a receive filter and the second acoustic filter comprises a transmit filter.

20. A method of fabricating a device, the method comprising:
forming a first substrate comprising a first side and a second side opposite to the first side;
forming a first piezoelectric layer on the first side of the first substrate;
forming a plurality of first electrodes on the first piezoelectric layer; and
forming a first vertical interconnect access (via) extending through the first substrate and the first piezoelectric layer to couple a first one of the plurality of first electrodes to the second side of the first substrate.

21. The method of claim 20, further comprising forming a capacitor on the second side of the first substrate coupled to one of the plurality of first electrodes.

22. The method of claim 20, further comprising forming an inductor on the second side of the first substrate coupled to one of the plurality of first electrodes.

23. The method of claim 21, wherein forming the first via comprises:
etching a void through the first substrate and the first piezoelectric layer; and
forming a first metal layer on the second side of the first substrate and in the void,
wherein a portion of the first metal layer comprises a first electrode of the capacitor.

24. The method of claim 23, further comprising forming an interconnect configured to couple the device to a package substrate;
wherein:
forming the capacitor further comprises:
forming a dielectric layer on the first electrode of the capacitor; and
forming a second metal layer on the dielectric layer, the second metal layer comprising a second electrode of the capacitor; and
forming the interconnect comprises forming the interconnect on the second metal layer.

25. The method of claim 20, further comprising:
coupling a second device on a second substrate to the first side of the first substrate, wherein a polymer layer is disposed between the first side of the first substrate and the second device and the polymer layer forms an air cavity; and
forming a through-polymer via through the polymer layer and extending between the first via and the second device.
